(19) United States
(12) Patent Application Publication
(10) Pub. No.: US 2012/0273844 A1
(43) Pub. Date: Nov. 1, 2012

(54) MAGNETIC RANDOM ACCESS MEMORY AND METHOD OF MANUFACTURING THE SAME

(75) Inventors: Masayoshi IWAYAMA, Yokohama-shi (JP); Yoshiaki Asao, Kawasaki-shi (JP)

(73) Assignee: KABUSHIKI KAISHA TOSHIBA, Tokyo (JP)

(21) Appl. No.: 13/236,565

(22) Filed: Sep. 19, 2011

(30) Foreign Application Priority Data
Apr. 28, 2011 (JP) 2011-100789

(51) Int. Cl. H01L 29/82; H01L 21/20

(52) U.S. Cl. 257/252; 438/3; 257/E29.323; 257/E21.09

(57) ABSTRACT

According to one embodiment, a magnetic random access memory includes a first gate electrode and a second gate electrode arranged at a predetermined pitch in a first direction, and extending in a second direction perpendicular to the first direction, a first magnetoresistive element formed above a portion between the first gate electrode and the second gate electrode, an electrode layer formed in a position higher than the first magnetoresistive element, and formed to have a distance which is a half of the pitch from the first magnetoresistive element in the first direction, an interconnection formed in a position higher than the electrode layer, and extending in the first direction, and a first via which connects the first magnetoresistive element and the interconnection, and the electrode layer and the interconnection, by using one conductive layer.

### CROSS-REFERENCE TO RELATED APPLICATIONS

This application is based upon and claims the benefit of priority from prior Japanese Patent Application No. 2011-100789, filed Apr. 28, 2011, the entire contents of which are incorporated herein by reference.

### FIELD

Embodiments described herein relate generally to a magnetic random access memory (MRAM) using a via that comes in contact with layers having different heights at the same time.

### BACKGROUND

A magnetic random access memory (to be referred to as an MRAM hereinafter) is a general term of nonvolatile solid-state memories capable of retaining and reading out stored information at any time by using the change in resistance of a barrier layer caused by the magnetization direction of a ferromagnetic material. A cell of the MRAM normally has a structure in which a plurality of ferromagnetic layers and a plurality of barrier layers are stacked.

When the size of an MTJ (Magnetic Tunnel Junction) element is decreased in a conventional MRAM in which data is written by using a magnetic field generated by a wiring current, the retention increases, and this often increases an electric current required for data write. In this conventional MRAM, it is difficult to achieve a small electric current and a small cell size for obtaining a large capacity at the same time.

As a write method for solving this problem, a spin transfer torque MRAM using the spin transfer torque (STT) write method has been proposed. In the spin transfer torque MRAM, information is written by directly supplying an electric current to the MTJ element, and changing the magnetization direction in a free layer in accordance with the direction of this electric current.

In this spin transfer torque MRAM, the cell area must be reduced in order to increase the cell capacity. On the other hand, when the cell area is reduced, the via-to-via distance decreases, so it is necessary to lay out vias at an interval equal to a minimum feature size F. However, this via layout at the minimum feature size F is difficult from the viewpoint of exposure, so exposure must be performed a plurality of number of times. This may increase the manufacturing cost.

### BRIEF DESCRIPTION OF THE DRAWINGS

FIG. 1 is a plan view showing the layout of a memory cell array of a magnetic random access memory according to an embodiment;

FIG. 2A is a sectional view taken along a line IIA-IIA in FIG. 1;

FIG. 2B is a sectional view taken along a line IIB-IIB in FIG. 1;

FIG. 3 is a sectional view showing a peripheral circuit portion of the magnetic random access memory according to the embodiment; and

FIG. 4 is a plan view showing the cell array layout of the magnetic random access memory according to the embodiment.

### DETAILED DESCRIPTION

In general, according to one embodiment, a magnetic random access memory includes a first gate electrode and a second gate electrode arranged at a predetermined pitch in a first direction, and extending in a second direction perpendicular to the first direction, a first magnetoresistive element formed above a portion between the first gate electrode and the second gate electrode, an electrode layer formed in a position higher than the first magnetoresistive element, and formed to have a distance which is a half of the pitch from the first magnetoresistive element in the first direction, an interconnection formed in a position higher than the electrode layer, and extending in the first direction, and a first via which connects the first magnetoresistive element and the interconnection, and the electrode layer and the interconnection, by using one conductive layer.

This embodiment is a resistance change memory using a resistance change element as a cell, and a spin transfer torque magnetic random access memory will be taken as an example. The embodiment will be explained below with reference to the accompanying drawings. In the following explanation, the same reference numerals denote the same parts throughout the drawings.

### [1] Layout

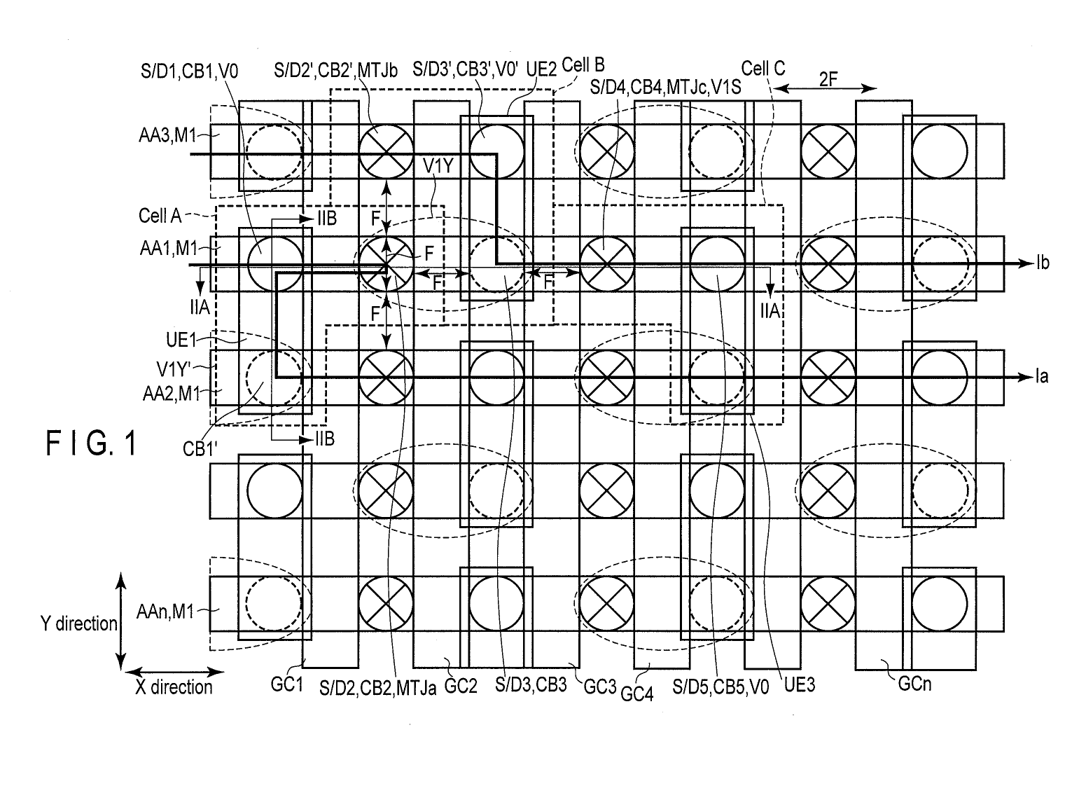

The layout of a memory cell array of the magnetic random access memory according to the embodiment will be explained below with reference to FIG. 1. Note that this layout is an 8F² type layout.

As shown in FIG. 1, a plurality of element regions (active areas) AA (AA1 to AAn) run in the X direction (a first direction), and a plurality of gate electrodes GC (GC1 to GCn) run in the Y direction (a second direction) perpendicular to the first direction. A plurality of upper interconnections (bit lines) M1 running in the X direction are respectively arranged above the plurality of element regions AA.

Bit line contacts CB (e.g., CB1 to CBn) are arranged on the element regions AA between the gate electrodes GC adjacent to each other in the X direction. Magnetic tunnel junction elements (resistance change elements) MTJ (e.g., MTJa to MTJc) are arranged on the bit line contacts CB adjacent to each other in the Y direction on one side of the gate electrodes GC.

A pitch P of the gate electrodes GC arranged in the X direction is 2F (F: a minimum feature size). The distance between the gate electrodes GC adjacent to each other in the X direction is F. A distance A between the magnetic tunnel junction elements MTJ adjacent to each other in the X direction is 3F. A distance B between the magnetic tunnel junction elements MTJ adjacent to each other in the Y direction is F. A distance C between the bit line contacts CB adjacent to each other in the X direction is F. Accordingly, the distances B and C are half the pitch P.

In a cell A, source/drain regions S/D1 and S/D2 are respectively formed in a first element region AA1 on the two sides of a gate electrode GC1. Bit line contacts CB1 and CB2 are respectively arranged on the source/drain regions S/D1 and S/D2. A via V0 is formed on the bit line contact CB1. On the other hand, a magnetic tunnel junction element MTJa is formed on the bit line contact CB2. A first upper electrode UE1 is formed on the via V0. The first upper electrode UE1 has an island-like shape, and extends to a portion above a second element region AA2 adjacent to the first element region AA1 in the Y direction. A via V1Y′ is formed on the first upper electrode UE1 above the second element region AA2.

In a cell B, bit line contacts CB2′ and CB3′ are respectively arranged on a third element region AA3 on the two sides of a gate electrode GC2. A magnetic tunnel junction element MTJb is formed on the bit line contact CB2′. On the other hand, a via V0′ is formed on the bit line contact CB3′. A second upper electrode UE2 is formed on the via V0′. The second upper electrode UE2 has an island-like shape, and extends to a portion above the first element region AA1 adjacent to the third element region AA3 in the Y direction.

In this embodiment, the magnetic tunnel junction element MTJa and upper interconnection M1 in the cell A and the second upper electrode UE2 and upper interconnection M1 in the cell B are simultaneously connected by using a common via V1Y. The opening of the via V1Y is, e.g., an ellipse or rectangle (having a length of, e.g., about 3F) that is long in the X direction. Note that the magnetic tunnel junction element MTJa and second upper electrode UE2 are arranged at different heights.

In the first element region AA1, the magnetic tunnel junction element MTJa of the cell A and a magnetic tunnel junction element MTJc of a cell C are juxtaposed in the X direction. The bridged via V1Y for simultaneously connecting the layers (the magnetic tunnel junction element MTJa and upper electrode UE2) having different heights is formed on the magnetic tunnel junction element MTJa. A single via V1S for connecting only the magnetic tunnel junction element MTJc is formed on it. That is, the bridged vias V1Y and single vias V1S are alternately arranged on the plurality of magnetic tunnel junction elements MTJ arranged in the X direction.

An electric current Ia of the cell A flows in the order of the upper interconnection M1 above the first element region AA1, the via V1Y, the magnetic tunnel junction element MTJa, the bit line contact CB2, the source/drain regions S/D2 and S/D1, the bit line contact CB1, the via V0, the upper electrode UE1, the via V1Y′, and the upper interconnection M1 above the second element region AA2.

An electric current Ib of the cell B flows in the order of the upper interconnection M1 above the third element region AA3, the magnetic tunnel junction element MTJb, the bit line contact CB2′, source drain regions S/D2′ and S/D3′, a bit line contact CB3′, the via V0′, the upper electrode UE2, the via V1Y, and the upper interconnection M1 above the first element region AA1.

### [2] Sectional Structure

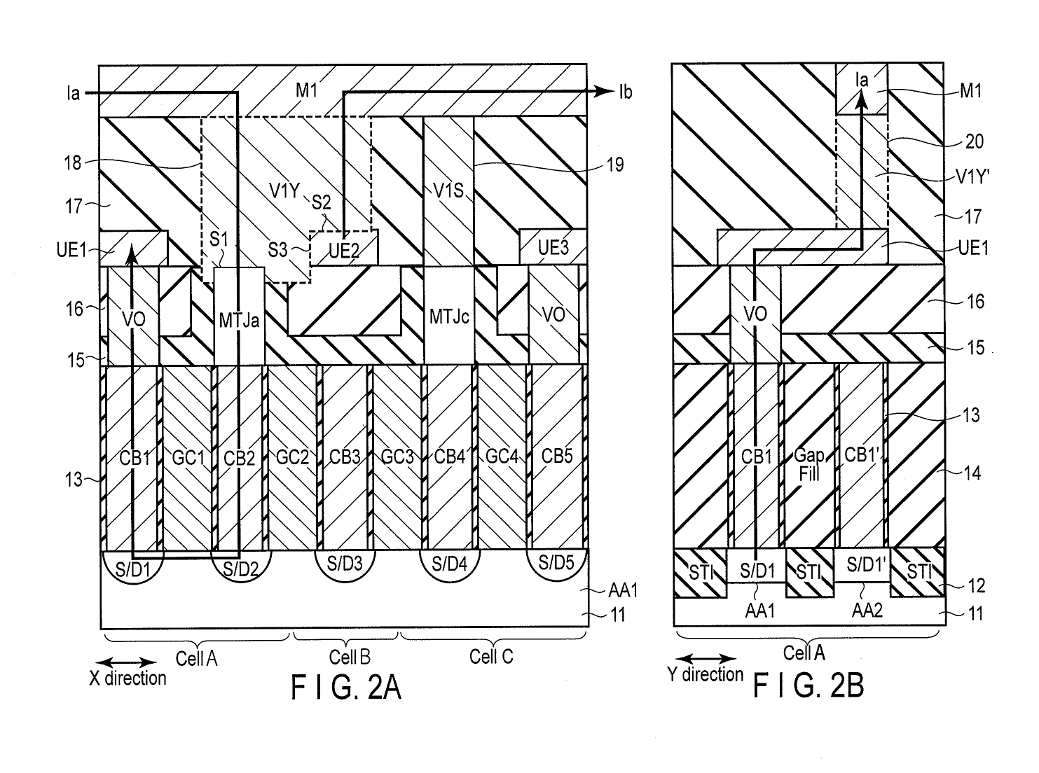

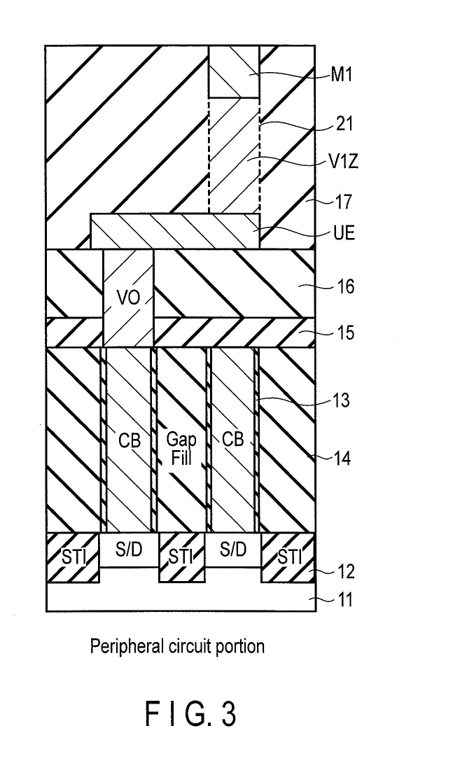

The sectional structure of the memory cell of the magnetic random access memory according to the embodiment will be explained below with reference to FIGS. 2A and 2B. The sectional structure of a peripheral circuit portion of the magnetic random access memory according to the embodiment will be explained below with reference to FIG. 3.

As shown in FIG. 2A, gate electrodes GC1 to GC4 are formed on a semiconductor substrate 11, and sidewall insulating films 13 are formed on the two side surfaces of each of the gate electrodes GC1 to GC4. Bit line contacts CB1 to CB5 are formed between the gate electrodes GC1 to GC4 adjacent to each other. The bit line contacts CB1 to CB5 are respectively connected to source/drain regions S/D1 to S/D5 in the element region AA1.

In the cell A, the magnetic tunnel junction element MTJa is formed on the bit line contact CB2, and the first upper electrode UE1 is formed on the via V0 on the bit line contact CB1. In the cell B, the second upper electrode UE2 is formed above the bit line contact CB3. In the cell C, the magnetic tunnel junction element MTJc is formed on the bit line contact CB4, and a third upper electrode UE3 is formed on the via V0 on the bit line contact CB5.

The magnetic tunnel junction element MTJa of the cell A and the second upper electrode UE2 of the cell B are arranged at different heights, and connected to the upper interconnection M1 via the bridged via V1Y. The lower portion of the via V1Y has first, second, and third surfaces S1, S2, and S3 forming steps. The first surface S1 is in contact with the upper surface of the magnetic tunnel junction element MTJa, the second surface S2 is in contact with the upper surface of the second upper electrode UE2, and the third surface S3 is in contact with the side surface of the second upper electrode UE2.

In the cell C, the magnetic tunnel junction element MTJc is connected to the upper interconnection M1 via the via V1S.

As shown in FIG. 2B, the first upper electrode UE1 of the cell A extends in the Y direction from the first element region AA1 to the second element region AA2. The via V1Y′ is formed on the first upper electrode UE1 above the second element region AA2.

In the peripheral circuit portion as shown in FIG. 3, the bit line contacts CB are connected to the source/drain regions S/D, and the upper electrode UE is connected to one bit line contact CB via the via V0. In addition, the upper interconnection M1 is connected to the upper electrode UE via a via V1Z.

### [3] Manufacturing Method

A method of manufacturing the memory cell of the magnetic random access memory according to the embodiment will be explained below with reference to FIGS. 2A and 2B.

First, an element isolation region 12 having an STI (Shallow Trench Isolation) structure is formed in a semiconductor substrate 11, thereby isolating element regions AA1 and AA2. Then, gate electrodes GC1 to GC4 are formed on the semiconductor substrate 11, and sidewall insulating films 13 are formed on the side surfaces of the gate electrodes GC1 to GC4. After that, source/drain regions S/D1 to S/D5 and S/D1′ are formed in the element regions AA1 and AA2.

Subsequently, a gap fill film 14 is buried between the gate electrodes GC1 to GC4. After that, the gap fill film 14 is selectively removed to form trenches that expose the source/drain regions S/D1 to S/D5 and S/D1′. A conductive material is buried in these trenches, thereby forming bit line contacts CM to CB5 and CB1′ respectively connected to the source/drain regions S/D1 to S/D5 and S/D1′. Magnetic tunnel junction elements MTJa and MTJc are respectively formed on the bit line contacts CB2 and CB4.

A protective film 15 covering the magnetic tunnel junction elements MTJa and MTJc is formed, and an interlayer insulating film 16 is formed on the protective film 15. Examples of the protective film 15 are SiN and AlOₓ. The protective film 15 and interlayer insulating film 16 are planarized to expose the magnetic tunnel junction elements MTJa and MTJc. The protective film 15 and interlayer insulating film 16 are then selectively removed, thereby forming via holes that expose the bit line contacts CB1 and CB5. A conductive material is buried in these via holes and planarized, thereby forming vias V0.

Subsequently, upper electrodes UE1 to UE3 made of, e.g., TiN are formed. An interlayer insulating film 17 covering the upper electrodes UE1 to UE3 is formed. Via holes 18, 19, and 20 are selectively formed in the interlayer insulating film 17, and a conductive material is buried in the via holes 18, 19, and 20 and planarized, thereby forming vias V1Y, V1S, and V1Y′. In the formation of the via holes 18, 19, and 20, mask formation and exposure are performed twice for the via holes 18 and 20 and for the via hole 19. The via hole 18 simultaneously exposes the magnetic tunnel junction element MTJa of the cell A and the upper electrode UE2 of the cell B. The via hole 19 exposes the magnetic tunnel junction element MTJc of the cell C. The via hole 20 exposes the upper electrode UE1 of the cell A. After that, an upper interconnection M1 is formed on the vias V1Y, V1S, and V1Y′.

### [4] Cell Layout

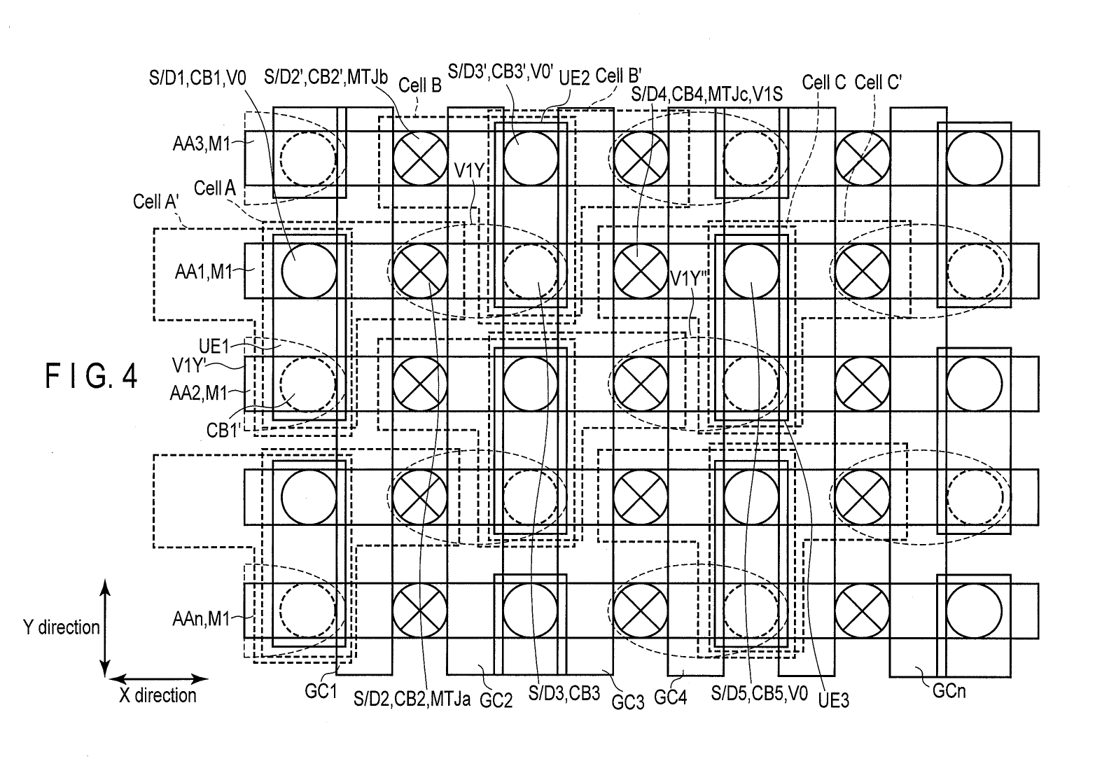

The cell layout of the magnetic random access memory according to the embodiment will be explained below with reference to FIG. 4. Note that FIG. 1 described above shows a simplified cell layout to allow easy understanding.

In this embodiment, two cells share the upper electrode UE, the contact V0 connected to the upper electrode UE, the bit line contact CB, the source/drain regions S/D, and the via V1Y.

For example, as shown in FIG. 4, cells A and A′ share the upper electrode UE1, contact V0, bit line contact CB1, source/drain regions S/D1, and via V1Y′. Cells B and B′ share the upper electrode UE2, contact V0′, a bit line contact CB3′, source/drain regions S/D3′, and the via V1Y. Cells C and C′ share the upper electrode UE3, contact V0, bit line contact CB5, source/drain regions S/D5, and a via V1Y″.

### [5] Effects

Assuming that the magnetic tunnel junction element MTJa and upper interconnection M1 and the upper electrode UE2 and upper interconnection M1 are respectively connected by using different vias Va and Vb, if the distance between the vias Va and Vb is set to F in order to reduce the cell area, simultaneous exposure of the vias Va and Vb becomes difficult, so masking and exposure must be performed twice for the vias Va and Vb.

In this embodiment, however, the magnetic tunnel junction element MTJa and upper interconnection M1 and the upper electrode UE2 and upper interconnection M1 are respectively simultaneously connected by using the bridged via V1Y. Even when the vias or contacts are arranged at the interval F, therefore, exposure for the formation of the via for making the above-mentioned two connections need only be performed once. Also, the via V1S and the via V1Z in the peripheral circuit portion can be exposed at the same time because they are spaced apart by F or more. Accordingly, via formation of this embodiment need only be performed twice for exposure for the vias V1S and V1Z, and exposure for the bridged via V1Y. This makes it possible to reduce the number of times of exposure, and reduce the cost.

In this embodiment as described above, vias or contacts are arranged at the interval F, and the bridged via V1Y for simultaneously connecting the layers (the magnetic tunnel junction element MTJa and upper electrode UE2) having different heights is formed. This makes it possible to reduce the cell area and suppress the increase in cost at the same time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic random access memory comprising:
a first gate electrode and a second gate electrode arranged at a predetermined pitch in a first direction, and extending in a second direction perpendicular to the first direction;
a first magnetoresistive element formed above a portion between the first gate electrode and the second gate electrode;
an electrode layer formed in a position higher than the first magnetoresistive element, and formed to have a distance which is a half of the pitch from the first magnetoresistive element in the first direction;
an interconnection formed in a position higher than the electrode layer, and extending in the first direction; and
a first via which connects the first magnetoresistive element and the interconnection, and the electrode layer and the interconnection, by using one conductive layer.

2. The memory according to claim 1, further comprising a second magnetoresistive element formed to have the distance from the first magnetoresistive element in the second direction.

3. The memory according to claim 1, further comprising:
a second magnetoresistive element juxtaposed with the first magnetoresistive element in the first direction; and
a second via which connects only the second magnetoresistive element and the interconnection,
wherein the first via and the second via are alternately arranged in the first direction.

4. The memory according to claim 1, wherein the first magnetoresistive element and the electrode layer are positioned in different memory cells.

5. The memory according to claim 1, wherein two different cells share the electrode layer.

6. A method of manufacturing a magnetic random access memory, comprising:
forming a first gate electrode and a second gate electrode arranged at a predetermined pitch in a first direction, and extending in a second direction perpendicular to the first direction;
forming a magnetoresistive element above a portion between the first gate electrode and the second gate electrode;
forming an electrode layer in a position higher than the first magnetoresistive element, and having a distance which is a half of the pitch from the first magnetoresistive element in the first direction;
forming an interlayer insulating film covering the magnetoresistive element and the electrode layer;
selectively removing the interlayer insulating film, forming a via hole which simultaneously exposes the magnetoresistive element and the electrode layer;
forming a via by filling the via hole with a conductive layer; and
forming an interconnection extending in the first direction on the via, and simultaneously connecting the magnetoresistive element and the interconnection, and the electrode layer and the interconnection, by using the via.
